(19) United States
(12) Patent Application Publication
(10) Pub. No.: US 2026/0205132 A1
(43) Pub. Date: Jul. 16, 2026

(54) CIRCUIT AND SYSTEM FOR PROCESSING AN ANALOG INPUT SIGNAL, AND METHOD OF USING THEREOF

(71) Applicant: YEDA RESEARCH AND DEVELOPMENT CO. LTD., Rehovot (IL)

(72) Inventors: Yonina C. ELDAR, Rehovot (IL); Shlomi SAVARIEGO, Rehovot (IL); Yhonatan KVICH, Rehovot (IL)

(21) Appl. No.: 19/449,680

(22) Filed: Jan. 15, 2026

Related U.S. Application Data
(60) Provisional application No. 63/745,935, filed on Jan. 16, 2025.

(51) Int. Cl. H03M 1/12

(52) U.S. Cl. CPC H03M 1/124

(57) ABSTRACT

The present invention may include an electric circuit for sampling an input signal, including a modulo circuit configured to apply a modulo operation to the input signal to generate a folded signal exhibiting higher bandwidth than the input signal, an analog mixer circuit configured to multiply the folded signal by a periodic signal to produce a mixed signal, a low-pass filter circuit configured to filter the mixed signal to generate a filtered signal, and an analog-to-digital converter circuit having a bandwidth suited for the input signal and configured to sample the filtered signal to generate a digital output signal representative of the folded signal. A system for sampling an input signal may include the circuit, an input device, a modulo recovery circuit, and a processor configured to perform operations based on a recovered signal.

### CROSS-REFERENCE TO RELATED APPLICATIONS

This application claims priority of U.S. Application No. 63/745,935, titled “PRACTICAL MODULO SAMPLING: MITIGATING HIGH-FREQUENCY COMPONENTS”, filed Jan. 16, 2025, which is hereby incorporated by reference in its entirety.

### FIELD OF INVENTION

The present invention relates to the field of electrical circuits, and more particularly to a system, circuit and method of processing an input analog signal.

### BACKGROUND

Analog-to-digital converters (ADCs) serve a fundamental role in converting analog signals into digital format for processing within digital signal processing systems. The cost and power requirements of ADCs tend to escalate with higher sampling rates, making it advantageous to operate at rates close to the minimum rate dictated by the Shannon-Nyquist sampling theorem, which states that bandlimited signals can be accurately represented by uniform samples taken at a rate at least double the maximum frequency present in the signal.

Another consideration in ADC design relates to dynamic range. To prevent signal clipping and consequent information loss, an ADC's dynamic range typically exceeds that of the input analog signal. When dynamic range limits are surpassed, clipping causes data loss. Expanding dynamic range can help address this issue but may add quantization noise and require power-intensive, high-resolution ADCs.

Various strategies have emerged to address clipping. Some techniques leverage inherent correlation in bandlimited signal samples taken above the Nyquist rate, reconstructing missing information due to clipping through oversampling. Other approaches exploit spectral gaps in multiband systems to discern original from clipped signals. However, these methods may demand oversampling or prior knowledge of spectral gaps. Clipping can also be mitigated through attenuation, though this risks reducing low-amplitude signals below the noise floor. Variable gain attenuators, such as automatic gain controls and companders, adjust to preserve signal integrity without disproportionately affecting smaller amplitude signals.

An alternative strategy involves applying a modulo operation to the input signal before sampling to limit its dynamic range. This approach, sometimes referred to as unlimited sampling, relies on folded or modulo samples for signal recovery. When applying the modulo operator to a bandlimited signal, the resulting folded signal exhibits a broadened bandwidth. The employed ADC is therefore expected to be capable of handling these increased frequency components. Typically, the used ADC is designed for bandwidths significantly higher than that of the input signal, leading to samples that closely resemble the folded signal values.

In scenarios where the sampler is realistically capable of handling a sampling rate matched to the original input signal rather than the expanded bandwidth of the folded signal, the folded signal would need to be processed through a Low-Pass Filter (LPF) filter before sampling. This energy loss during filtering can alter measurements, potentially undermining modulo recovery techniques that fail to consider such distortions. The error introduced by ignoring high-frequency components may be substantial compared to the quantization error typically associated with classical sampling schemes.

An ADC fundamentally operates by alternating between two phases: track-and-hold (T/H) and quantization. During the T/H phase, the ADC follows the signal's variations. Once accurate tracking is achieved, the ADC holds this value steady, allowing the quantizer to transform the signal's amplitude into a digital representation. These steps must be completed before acquiring the next sample. It is common in signal processing to idealize the ADC as a pointwise sampler that captures the signal at a consistent rate of samples per second. Nonetheless, due to the inherent limitations of analog circuits, the T/H function has a finite frequency tracking capability and cannot follow signals that change too quickly. Practically, an LPF with a specific cutoff frequency approximates the T/H function's bandwidth limitation. Commercial ADCs typically specify this internal LPF cutoff frequency to be higher than the maximum sampling rate, but within the same order of magnitude.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

Embodiments of the invention may include an electric circuit for sampling an analog input signal. Embodiments of the circuit may include a modulo circuit configured to apply a modulo operation to the input signal, thereby generating a folded signal whose bandwidth may be higher than that of the input signal. Embodiments of the circuit may further include an analog mixer circuit configured to multiply the folded signal by a periodic signal to produce a mixed signal, a low-pass filter circuit configured to filter the mixed signal, to generate a filtered signal, and an Analog-to-Digital Converter (ADC) circuit. The ADC may be configured to sample the filtered signal to generate a digital output signal representative of the folded signal. As explained herein, the ADC may not require a working bandwidth suited for the folded signal. Instead, the ADC may have a working bandwidth that is suited for the analog input signal. As explained herein, this difference may allow embodiments of the invention to present several benefits over currently available methods and systems of signal processing, manifested for example in circuit availability, simplicity, cost and power consumption.

According to some embodiments, the electric circuit may include, or may be associated with or connected to a recovery module, configured to apply a modulo recovery operation to the digital output signal. The recovery module may thereby generate a recovered signal representative of the input signal, which may be further analyzed or processed by software and/or hardware as described herein, according to individual implementation needs.

As explained herein, the sampling rate Fₛ of the ADC circuit may exceeds a Nyquist frequency of the input signal, and may be lower than a Nyquist frequency of the folded signal.

Additionally, the periodic signal may have frequency Fₚ which exceeds a Nyquist frequency of the input signal but may be lower than a Nyquist frequency of the folded signal.

Embodiments of the invention may further include a signal generator module, which may be, or may include a Step Recovery Diode (SRD). The SRD may be configured to generate the periodic signal as a delta comb having frequency Fₚ.

Additionally, or alternatively, the low-pass filter circuit may have a cutoff frequency that exceeds a Nyquist frequency of the input signal, and is lower than a Nyquist frequency of the folded signal.

Embodiments of the invention may include a folding indicator circuit. The folding indicator circuit may be configured to generate a 1-bit folding indication, signifying whether the modulo circuit has applied a fold to the input signal since a previous sample; and incorporate the folding indication into a least significant bit of the digital output signal.

Embodiments of the invention may further include, or be associated with a modulo recovery circuit. The modulo recovery circuit may be configured to apply an unwrapping algorithm on the digital output signal, based on the folding indication, to generate a recovered signal representative of the input signal.

According to some embodiments, the analog mixer circuit may be configured to convert the folded signal and the periodic signal to differential currents, and to multiply the differential currents using a trans-linear core as known in the art, to produce the mixed signal.

Embodiments of the invention may include a system for processing analog signals. Embodiments of the system may include an input device, configured to generate an analog input signal and a modulo circuit configured to apply a modulo operation to the input signal, thereby generating a folded signal, that exhibits a higher bandwidth than the analog input signal.

Embodiments of the system may further include an analog mixer circuit configured to multiply the folded signal by a periodic signal to produce a mixed signal; a low-pass filter circuit configured to filter the mixed signal to generate a filtered signal; and an ADC circuit. The ADC circuit may have a bandwidth suited for the input signal, and configured to sample the filtered signal at a sampling rate that is lower than a Nyquist frequency of the folded signal. The ADC may thereby generate a digital output signal representative of the folded signal.

Embodiments of the system may further include or be associated with a modulo recovery circuit configured to apply a modulo recovery operation to the digital output signal to generate a digital recovered signal representative of the input signal. The modulo recovery circuit may be implemented by software, hardware, or any combination thereof, as known in the art.

Embodiments of the system may further include, or be associated with a processor configured to perform at least one software or hardware based downstream operation based on the recovered signal, to process or analyze the analog input signal.

According to some embodiments, the periodic signal has a frequency Fₚ that exceeds a Nyquist frequency of the input signal, and is lower than a Nyquist frequency of the folded signal.

Embodiments of the system may further include a signal generator module that may be, or may include a Step Recovery Diode (SRD). The SRD may be configured to generate the periodic signal as a delta comb.

Embodiments of the system may further include a folding indicator circuit configured to: generate a 1-bit folding indication signifying whether the modulo circuit has applied a fold to the input signal since a previous sample; and incorporate the folding indication into a least significant bit of the digital output signal.

Embodiments of the invention may include a method of processing an analog input signal. Embodiments of the method may include applying a modulo circuit to the input signal to generate a folded signal, wherein the folded signal exhibits a higher bandwidth than the input signal; obtaining a periodic signal; applying a multiplier circuit on the folded signal and the periodic signal to produce a mixed signal; filtering the mixed signal using a low-pass filter to generate a filtered signal; applying an ADC circuit on the filtered signal to generate a digital signal representative of the folded signal, wherein a sampling rate of the ADC circuit is lower than a Nyquist frequency of the folded signal; applying a modulo recovery operation to the digital signal to generate a recovered signal representing a digital version of the input signal; and performing at least one software or hardware based operation on the recovered signal.

Embodiments of the method may further include generating a 1-bit folding indication signifying whether a fold has been applied to the input signal since a previous sample; incorporating the folding indication into a least significant bit of the digital signal; and applying the modulo recovery operation by performing an unwrapping algorithm on the digital signal based on a folding indication. According to some embodiments, the analog input signal may be generated by an input device. For example, the input device may include a sensor configured to detect physical phenomena and generate the analog input signal as an analog representation thereof, a transducer configured to convert physical quantities into electrical signals, a communication receiver configured to receive wired or wireless transmitted signals, and any combination thereof.

In some aspects, the sensor may include, for example, an acoustic sensor, an optical sensor, an electromagnetic sensor, or any other sensor type. The transducer may be configured to convert various physical quantities, such as temperature, pressure, light intensity, or motion, into corresponding electrical signals. The communication receiver may be configured to receive signals transmitted over wired communication channels, wireless communication channels, or a combination thereof.

Embodiments of the invention may further include performing at least one software or hardware based operation on the recovered signal. The operation may be selected from: performing signal analysis, performing signal filtering, performing feature extraction, performing pattern recognition, performing data compression, performing data storage, performing data transmission, performing signal visualization, performing control system actuation, and any combination thereof. In some aspects, signal analysis may include spectral analysis, time-domain analysis, or statistical analysis of the recovered signal.

For example, signal filtering may include applying digital filters to remove noise or isolate specific frequency components. Feature extraction may include identifying characteristics of the recovered signal for use in classification or recognition tasks. Data storage may include storing the recovered signal or processed versions thereof in a memory or storage system. Data transmission may include transmitting the recovered signal or processed versions thereof over wired or wireless communication channels. Signal visualization may include displaying the recovered signal on a display device. Control system actuation may include using the recovered signal to control a physical system or device. Other such application-specific implementations may also be possible.

The foregoing general description of the illustrative embodiments and the following detailed description thereof are merely exemplary aspects of the teachings of this disclosure and are not restrictive.

### BRIEF DESCRIPTION OF FIGURES

The patent or application file contains at least one drawing executed in color. Copies of this patent or patent application publication with color drawing(s) will be provided by the Office upon request and payment of the necessary fee.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram depicting a computing device, which may be included within, or communicatively connected to, an embodiment of a system for processing an analog input signal, according to some embodiments.

FIG. 2A depicts a graph illustrating signal clipping in analog-to-digital conversion;

FIG. 2B depicts a graph comparing an original signal and a modulo-folded signal, according to some embodiments of the invention;

FIG. 2C depicts a graph showing a Fast Fourier Transform (FFT) comparison between the original signal of FIG. 2B and the modulo signal of FIG. 2B;

FIG. 2D depicts a graph illustrating the effect of applying a low-pass filter to a modulo signal, according to some embodiments of the invention;

FIG. 3A is a block diagram illustrating a modulo sampling and recovery system, as known in the art;

FIG. 3B is a block diagram illustrating a schematic example of implementation of a sampling and modulo recovery system for processing an input signal, according to some embodiments of the invention;

FIG. 4 is a block diagram illustrating another example for implementation of a system for sampling an analog input signal, according to some embodiments of the invention; and

FIG. 5 is a flow diagram depicting steps of a method of processing an analog input signal, according to some embodiments of the invention.

### DETAILED DESCRIPTION

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term “set” when used herein may include one or more items.

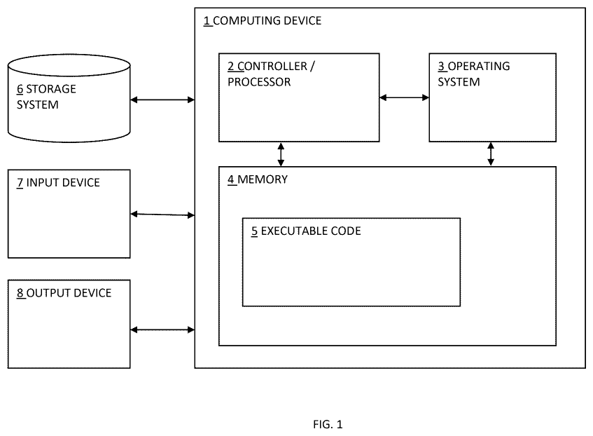

Reference is now made to FIG. 1, which is a block diagram depicting a computing device, which may be included within an embodiment of a system for processing an analog input signal according to some embodiments.

Computing device 1 may include a processor or controller 2 that may be, for example, a central processing unit (CPU) processor, a chip or any suitable computing or computational device, an operating system 3, a memory 4, executable code 5, a storage system 6, input devices 7 and output devices 8. Processor 2 (or one or more controllers or processors, possibly across multiple units or devices) may be configured to carry out methods described herein, and/or to execute or act as the various modules, units, etc. More than one computing device 1 may be included in, and one or more computing devices 1 may act as the components of, a system according to embodiments of the invention.

Operating system 3 may be or may include any code segment (e.g., one similar to executable code 5 described herein) designed and/or configured to perform tasks involving coordination, scheduling, arbitration, supervising, controlling or otherwise managing operation of computing device 1, for example, scheduling execution of software programs or tasks or enabling software programs or other modules or units to communicate. Operating system 3 may be a commercial operating system. It will be noted that an operating system 3 may be an optional component, e.g., in some embodiments, a system may include a computing device that does not require or include an operating system 3.

Memory 4 may be or may include, for example, a Random-Access Memory (RAM), a read only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short term memory unit, a long term memory unit, or other suitable memory units or storage units. Memory 4 may be or may include a plurality of possibly different memory units. Memory 4 may be a computer or processor non-transitory readable medium, or a computer non-transitory storage medium, e.g., a RAM. In one embodiment, a non-transitory storage medium such as memory 4, a hard disk drive, another storage device, etc. may store instructions or code which when executed by a processor may cause the processor to carry out methods as described herein.

Executable code 5 may be any executable code, e.g., an application, a program, a process, task, or script. Executable code 5 may be executed by processor or controller 2 possibly under control of operating system 3. For example, executable code 5 may be an application that may process an analog input signals further described herein. Although, for the sake of clarity, a single item of executable code 5 is shown in FIG. 1, a system according to some embodiments of the invention may include a plurality of executable code segments similar to executable code 5 that may be loaded into memory 4 and cause processor 2 to carry out methods described herein.

Storage system 6 may be or may include, for example, a flash memory as known in the art, a memory that is internal to, or embedded in, a micro controller or chip as known in the art, a hard disk drive, a CD-Recordable (CD-R) drive, a Blu-ray disk (BD), a universal serial bus (USB) device or other suitable removable and/or fixed storage unit. Data pertaining to an analog input signal may be stored in storage system 6 and may be loaded from storage system 6 into memory 4 where it may be processed by processor or controller 2. In some embodiments, some of the components shown in FIG. 1 may be omitted. For example, memory 4 may be a non-volatile memory having the storage capacity of storage system 6. Accordingly, although shown as a separate component, storage system 6 may be embedded or included in memory 4.

Input devices 7 may be or may include any suitable input devices, components, or systems, e.g., a detachable keyboard or keypad, a mouse and the like. Output devices 8 may include one or more (possibly detachable) displays or monitors, speakers and/or any other suitable output devices. Any applicable input/output (I/O) devices may be connected to Computing device 1 as shown by blocks 7 and 8. For example, a wired or wireless network interface card (NIC), a universal serial bus (USB) device or external hard drive may be included in input devices 7 and/or output devices 8. It will be recognized that any suitable number of input devices 7 and output device 8 may be operatively connected to Computing device 1 as shown by blocks 7 and 8.

A system according to some embodiments of the invention may include components such as, but not limited to, a plurality of central processing units (CPU) or any other suitable multi-purpose or specific processors or controllers (e.g., similar to element 2), a plurality of input units, a plurality of output units, a plurality of memory units, and a plurality of storage units.

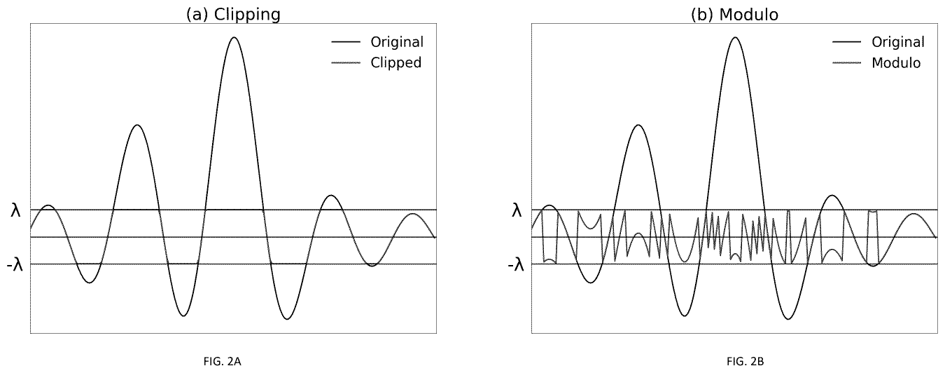

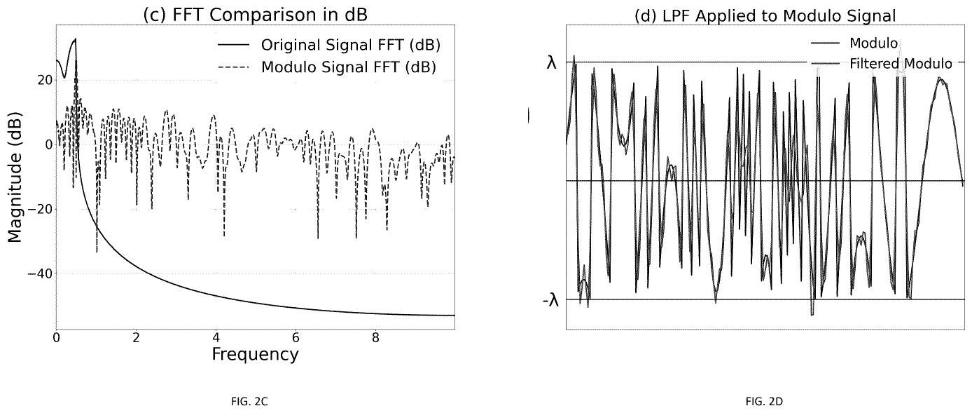

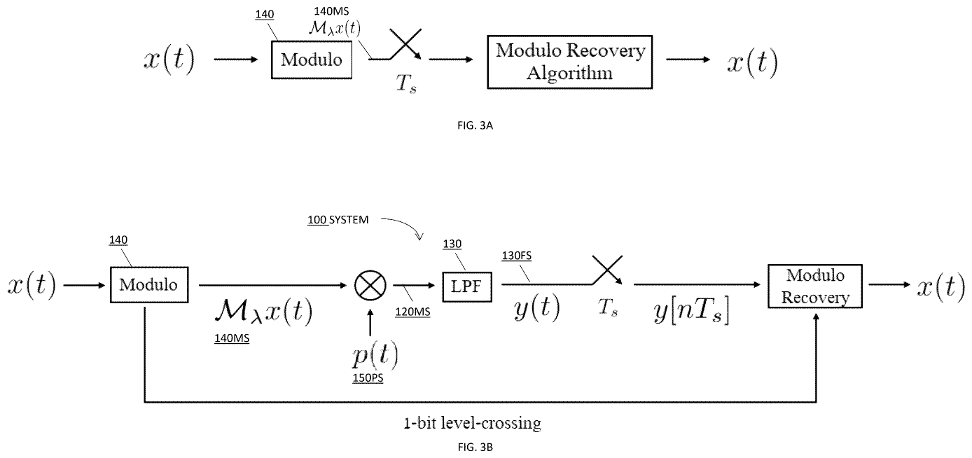

Referring now to FIG. 2A, which is a graph illustrating the concept of signal clipping (e.g., as part of analog-to-digital conversion). The graph depicts two waveforms plotted against time on the horizontal axis and amplitude on the vertical axis. A first (blue) waveform represents an original bandlimited signal that exhibits varying amplitude oscillations, with several peaks extending beyond defined threshold levels. A second (red) waveform represents the clipped version of the original signal. Two horizontal lines indicate the upper and lower boundaries of the dynamic range, labeled as λ and −λ respectively, which define the clipping thresholds. As shown in FIG. 2A, while the original signal exceeds these threshold boundaries at multiple points, the clipped signal is constrained to remain within the dynamic range defined by the λ boundaries, demonstrating information loss due to dynamic range limitation.

Referring now to FIG. 2B, which is a graph comparing an original analog signal and a modulo-folded signal as a function of time, which may be obtained by embodiments of the invention. A first curve labeled “Original” (blue) shows a bandlimited signal (e.g., the same as the original signal of FIG. 2A) that oscillates with varying amplitude, exceeding both the positive lambda and negative lambda boundaries at multiple points throughout the time interval. A second curve labeled “Modulo” (red) shows the result of applying a modulo operation to the original signal, where the signal values are constrained to remain within the range between negative lambda and positive lambda. The modulo signal exhibits rapid oscillations and discontinuities at locations where the original signal crosses the lambda boundaries, demonstrating the folding behavior characteristic of the modulo operation. FIG. 2B illustrates how the modulo operation compresses a high dynamic range signal into a limited amplitude range while introducing higher frequency components in the folded signal.

Referring now to FIG. 2C, which is a graph showing a Fast Fourier Transform (FFT) comparison in decibels (dB) between the original signal of FIGS. 2A and 2B and a modulo signal (e.g., the same as the modulo-folded signal of FIG. 2B). The horizontal axis represents frequency, while the vertical axis represents magnitude in dB. A first line (blue) represents the original signal's FFT in dB, which shows a peak magnitude at low frequencies and decreases smoothly and monotonically as frequency increases. A second line (red) represents the modulo folded signal FFT in dB, which exhibits significant oscillatory behavior across a wide frequency range. The comparison illustrates that the modulo operation introduces high-frequency components, far beyond the effective bandwidth of the original bandlimited signal.

Referring now to FIG. 2D, which is a time-based graph illustrating the effect of applying a Low-Pass Filter (LPF) to a modulo-folded signal. The graph includes two plotted signals: a modulo-folded signal (red, e.g., the same as modulo folded signal of FIG. 2B) and a filtered modulo signal (blue). The modulo signal exhibits sharp transitions characteristic of the folding operation applied to a bandlimited signal, with values constrained between negative lambda and positive lambda. The filtered modulo signal, obtained after passing through an LPF, displays a smoother waveform that follows the general trend of the modulo signal but lacks the high-frequency components. Most existing approaches assume an ideal pointwise sampler, wherein the Analog-to-digital converter (ADC) is capable of capturing the entire extended bandwidth of the folded signal, thereby necessitating a significantly more advanced ADC than would be required for the original input signal. However, such high-specification ADCs are neither cost-effective nor practical for real-world implementations. Directly employing an ADC suited to the original signal's bandwidth to sample the folded signal would result in removal of the high-frequency components during sampling, thereby introducing distortions that conventional recovery methods fail to address. As illustrated in FIG. 2D, the modulo signal becomes distorted after passing through an LPF, even when the cutoff frequency is well above the Nyquist rate of the input signal. This distortion illustrates the challenge addressed by the sampling approach described herein, where high-frequency components introduced by the modulo operation may be properly handled to enable accurate signal recovery using realistic ADCs.

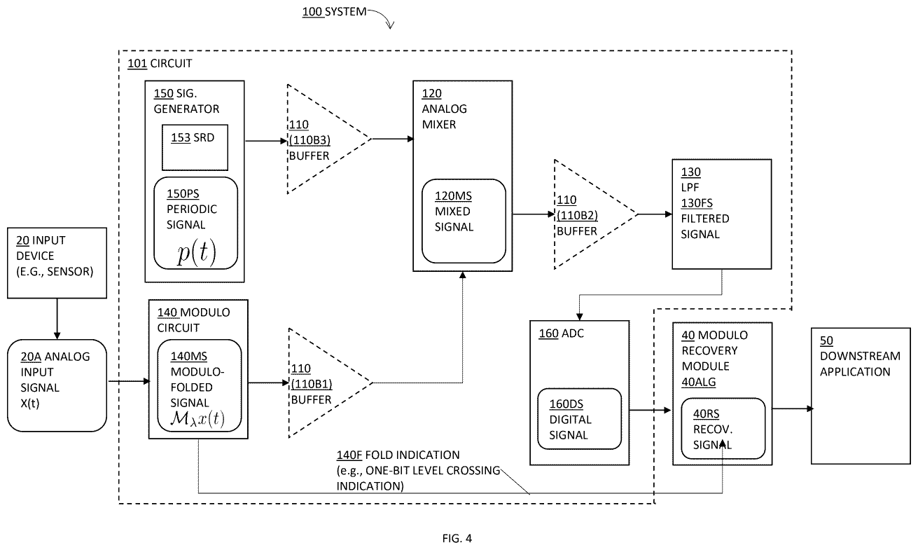

Reference is now made to FIG. 3A, which is a block diagram illustrating a naive modulo sampling and recovery system, as known in the art. As discussed herein, a modulo operation may remap real values of an input signal into a bounded interval [−λ, λ] for any λ>0. The modulo operation may thereby compress or “fold” the signal within a set dynamic range, to obtain a “folded” or “modulo folded” signal M_{λ}x (also denoted herein 140MS), as shown in equation 1 below:

$${ℳ}_{λ} x : = ( ( x + λ ) mod 2 λ ) - λ \qquad Eq . 1$$

As illustrated in FIG. 3A, an input bandlimited signal may be subjected to an analog modulo operation. The resulting signal may then be sampled by an ADC at a rate Tₛ that is less than the Nyquist rate T of the input bandlimited signal. In other words, a sampling frequency Fₛ of the ADC must exceed a Nyquist frequency (e.g., double the bandwidth) of the input bandlimited signal. It may be appreciated by a person skilled in the art that the sampling frequency Fₛ of the ADC should preferably exceed the Nyquist frequency of the input signal moderately, e.g., within the same order of magnitude, for practical reasons such as power consumption and ADC component cost.

When applying the modulo operator to a bandlimited signal, the resulting folded signal exhibits a significantly broadened bandwidth, as illustrated in FIG. 2C. The ADC employed should therefore be capable of handling these increased frequency components. Currently available solutions employ ADCs that are designed for bandwidths significantly (e.g., an order of magnitude) higher than that of the input signal. In scenarios where the sampler is realistically capable of only handling the sampling rate Tₛ, the folded signal must be processed through an LPF before sampling. As explained herein (e.g., in relation to FIG. 2D), this energy loss during filtering can significantly alter measurements, potentially undermining existing modulo recovery techniques that fail to consider such distortions. Such filtering error may be orders of magnitude greater than the quantization error typically associated with classical sampling schemes. Therefore, even with perfect modulo recovery, disregarding the high-frequency components leads to recovery outcomes that are inferior to both modulo and classical sampling approaches.

Reference is made to FIG. 3B and FIG. 4 which are block diagrams illustrating examples for implementation of a sampling and modulo recovery system 100 for processing an input signal 20A. Corresponding elements between FIG. 3B and FIG. 4 may be the same or similar. FIG. 3B relates to the mathematical discussion presented herein, while FIG. 4 provides additional implementation details.

System 100 may provide a comprehensive solution for analyzing analog signals. As shown in FIG. 4, system 100 may include a device or source 20 for obtaining input signal 20A, an electrical circuit 101 for sampling and/or digitizing input signal 20A, a recovery module 40 for recovering a digital version of input signal 20A, and optionally a downstream hardware and/or software application 50 that analyzes or utilizes the recovered signal 40RS.

For example, input device or source 20 may include a sensor configured to detect physical phenomena and generate input signal 20A as an analog representation thereof. Such a sensor may include, for example, an acoustic sensor, an optical sensor, an electromagnetic sensor, or any other type of transducer configured to convert physical quantities into electrical signals. In some cases, device or source 20 may include a communication receiver configured to receive transmitted signals, or any other source of analog signals.

Circuit 101 may include a modulo circuit 140, an analog mixer 120, an LPF 130, and ADC 160. These components may operate in conjunction to sample input signal 20A while addressing the high-frequency components introduced by the modulo operation, as described herein.

According to some embodiments, circuit 101 may include one or more buffers 110, such as first buffer 110B1, second buffer 110B2, and third buffer 110B3 as shown in FIG. 4. In some aspects, first buffer 110B1 may be positioned between modulo circuit 140 and analog mixer 120, second buffer 110B2 may be positioned between analog mixer 120 and LPF 130, and third buffer 110B3 may be positioned between signal generator 150 and analog mixer 120. Buffers 110 may be configured to provide signal isolation between circuit stages, impedance matching, and/or prevention of signal degradation.

As shown in FIG. 4, circuit 101 may be associated with, or communicatively connected to a recovery module 40. Recovery module 40 may be implemented in hardware, software, firmware, or any combination thereof.

In some aspects, recovery module 40 may include a processor configured to execute a modulo recovery algorithm to reconstruct a digital representation of input signal 20A from digital signal 160DS. Recovery module 40 may utilize fold indication 140F to assist in the recovery process, as elaborated herein. For example, recovery module 40 may include, or may be implemented by a computing device such as computing 1 of FIG. 1, configured to apply a modulo recovery algorithm, as known in the art, on fold indication 140F and digital signal 160DS, to reconstruct a digital representation 40RS of input signal 20A.

According to some embodiments, recovery module 40 may be configured to apply a modulo recovery algorithm 40ALG, also referred to as an unwrapping algorithm 40ALG as known in the art, to digital output signal 160DS to reconstruct a recovered signal that is a digital representation 40RS of input signal 20A. The modulo recovery algorithm may reverse the folding operation applied by modulo circuit 140, thereby recovering the original signal values from the folded samples.

In some embodiments, the modulo recovery algorithm 40ALG may operate based on the principle that bandlimited signals sampled above the Nyquist rate exhibit inherent correlation between successive samples. This correlation may be exploited to determine when and how the modulo operation has folded the signal. In some aspects, the algorithm may compute higher-order differences of the modulo samples, which may correspond to higher-order differences of the original signal when the sampling rate is sufficiently above the Nyquist rate. Signal reconstruction may then be achieved through cumulative summation of these differences.

Additionally, or alternatively, recovery module 40 may utilize fold indication 140F to assist in the unwrapping process. When fold indication 140F indicates that a fold has occurred since a previous sample, recovery module 40 may adjust the sample value by adding or subtracting multiples of 2λ to unwrap the folded value. In some aspects, recovery module 40 may interpret the least significant bit (LSB) of digital output signal 160DS as folding information rather than as part of the measurement value.

Additionally, or alternatively, the modulo recovery algorithm 40ALG may include an iterative refinement process. Recovery module 40 may initially estimate the original signal based on the folded samples and fold indication 140F, and may subsequently refine this estimate through iterative processing. The iterative process may leverage sparsity properties of the signal or may employ techniques such as an Iterative Shrinkage-Thresholding Algorithm (ISTA) to improve recovery accuracy.

Additionally, or alternatively, the modulo recovery algorithm 40ALG may be configured to handle quantization noise present in digital output signal 160DS. Recovery module 40 may be configured to guarantee accurate modulo recovery even in the presence of quantization noise, provided that the sampling rate exceeds a threshold (e.g., an oversampling rate greater than 3) and the ADC resolution meets a minimum requirement (e.g., at least 4 bits of resolution).

Additionally, or alternatively, recovery module 40 may apply a phase unwrapping technique to digital output signal 160DS. Phase unwrapping may involve detecting discontinuities in the folded signal that correspond to transitions across the 2 boundaries, and correcting these discontinuities by adding appropriate multiples of 2λ to restore continuity in the recovered signal. Once recovery module 40 has applied the modulo recovery algorithm to digital output signal 160DS, recovered signal 40RS may represent a digital version of input signal 20A. Recovered signal 40RS may then be provided to downstream application 50 for further processing or analysis.

Downstream application 50 may include any hardware or software configured to perform operations based on recovered signal 40RS. For example, downstream application 50 may be implemented by a computing device (e.g., computing device 1 of FIG. 1), and may include a processor or controller (e.g., processor 2 of FIG. 1) configured to perform at least one software or hardware based operation based on recovered signal 40RS.

Such operations may include, for example, signal analysis, signal filtering, feature extraction, pattern recognition, data compression, data storage, data transmission, signal visualization, control system actuation, or any other digital signal processing operation. The operation may be performed by executing software instructions on processor 2, or by dedicated hardware circuitry, or by a combination thereof.

Additionally, or alternatively, downstream application 50 may include signal analysis modules, data storage systems, communication interfaces, display devices, control systems, and/or any other components configured to process, store, transmit, visualize, or act upon the recovered signal. In some aspects, downstream application 50 may be implemented on the same device as recovery module 40, or may be implemented on a separate device communicatively coupled thereto.

Given a bandlimited input analog signal x(t) (also denoted 20A) with a Nyquist rate of T, system 100 may be configured to reconstruct the signal from modulo samples using realistic samplers that operate within a dynamic range of [−λ, λ]. The term “realistic sampler” may be used herein in reference ADCs that incorporate internal, or intrinsic LPF prior to sampling. This intrinsic LPF may exhibit a cutoff frequency that is aligned to the sampling rate without significantly surpassing it (e.g., within the same order of magnitude). In the context of the present invention, a realistic sampler may be implemented as an ADC that is adapted sample the bandlimited input analog signal x(t) as a sample frequency that (a) moderately exceeds (e.g., doubles, triples or quadruples) the Nyquist frequency of the input analog signal x(t), and (b) is well below (e.g., one order of magnitude below) the Nyquist frequency of the folded signal.

According to some embodiments of the invention, modulo circuit 140 may be configured to apply a modulo operation to the input signal, thereby generating a modulo folded signal 140 MS as depicted in FIG. 2B. As shown in FIG. 2C, folded signal 140 MS may exhibit a higher bandwidth (e.g., beyond one order of magnitude) than input signal 20A.

Analog mixer module 120 (also referred to herein as an analog multiplier 120) may be configured to multiply the folded signal 140 MS by a periodic function p(t) (also denoted herein 150PS), prior to sampling, thereby generating a mixed signal 120 MS.

In some aspects, periodic signal 150PS may have, or may be characterized by, a repetition period Tₛ that is less than the Nyquist rate T of the input signal x(t). For example, periodic signal 150PS may be a delta comb signal, having a repetition frequency Fₚ, wherein Fₚ (a) exceeds a Nyquist frequency of the input signal x(t) (20A), and (b) is lower than a Nyquist frequency of the folded signal 140 MS.

According to some embodiments, system 100 may include a signal generator 150 configured to generate periodic signal p(t) (150PS). As shown in FIG. 4, signal generator 150 may include a Step Recovery Diode (SRD) 153. SRD 153 may be configured to generate periodic signal 150PS as a delta comb having a repetition frequency Fₚ. In some aspects, SRD 153 may be part of a comb generator circuit that produces extremely short pulses to form the delta comb signal.

According to some embodiments, analog mixer 120 may be configured to convert folded signal 140 MS and periodic signal 150PS to differential currents, and to multiply the differential currents using a trans-linear core to produce mixed signal 120 MS. In some aspects, analog mixer 120 may include voltage-to-current converters that convert input voltages to differential currents that drive the trans-linear core.

Circuit 101 may pass mixed signal 120 MS through LPF 130 to produce a filtered signal y(t) (also denoted 130FS) as in equation 2 below:

$$y ( t ) = LPF ( p ( t ) {M}_{λ} x ) \qquad Eq . 2$$

According to some embodiments, LPF 130 may have a cutoff frequency that (a) moderately (e.g., within the same order of magnitude) exceeds a Nyquist frequency of the input signal 20A, and (b) is lower than a Nyquist frequency of the folded signal. Filtered signal y(t) (130FS) may thereby be bandlimited, with a Nyquist rate equal to, or moderately above Tₛ.

According to some embodiments, a sampling rate Fₛ of the ADC circuit 160 may (a) moderately (e.g., within the same order of magnitude) exceed a Nyquist frequency of the input signal x(t) (20A), and (b) be lower than a Nyquist frequency of the modulo folded signal 140 MS. In other words, ADC 160 may have a bandwidth suited for the input signal 20A rather than the higher bandwidth of the folded signal 140 MS. Filtered signal y(t) (130FS) may be sampled and quantized by ADC 160 at rate Tₛ (=1/Fₛ) resulting in a digital output signal y [nTₛ] (also denoted 160DS) as in equation 3 below. Digital output signal 160DS may be representative of the input signal 20A in its folded format (folded signal 140 MS).

$$y [ {nT}_{s} ] = LPF ( p ( t ) {M}_{λ} x ) [ {nT}_{s} ] \qquad Eq . 3$$

Signal y(t) may be bandlimited with a Nyquist rate of Tₛ, which matches the sampling rate, ensuring that the ADC processes only frequencies within this range. Pertaining to the example of periodic function p(t) as a delta comb in time, the resulting samples in Eq. 3 may be identical to the ideal pointwise samples of the folded signal. In other words, by using the analog mixer with a delta comb periodic function, system 100 may obtain samples that are equivalent to ideal pointwise samples of the folded signal, even though ADC 160 operates at a sampling rate suited to the original input signal 20A rather than the higher bandwidth of the folded signal 140 MS. This approach may achieve sampling quality comparable to an ideal high-specification ADC while using a realistic, lower-cost ADC that does not need to handle the extended bandwidth introduced by the modulo operation. Once these equivalent samples are obtained, any existing modulo recovery algorithm can be applied to reconstruct the original input signal.

In the context of the delta comb example provided herein, the benefit of using the realistic ADC sampler may be formalized as in equation 4, below:

$$if p ( t ) = {\sum }_{n ∈ ℤ} δ ( t - n {T}_{s} ) , then y [ n {T}_{s} ] = {M}_{λ} x [ n {T}_{s} ] \qquad Eq . 4$$

This may be proven as follows. From the assumption on p(t), a Fourier transform of p(t) may be given by equation 5 below:

$$P ( ω ) = {\sum }_{l ∈ ℤ} δ ( ω - \frac{2 π l}{{T}_{s}} ) . \qquad Eq . 5$$

Denoting z(t)=p(t) M_{λ}x(t), and using the Continuous-Time Fourier Transform (CTFT) and Discrete-Time Fourier Transform (DTFT) will derive equation 6 below:

$$Z ( ω ) = {\sum }_{l ∈ ℤ} ℱ \{ {M}_{λ} x \} ( ω - \frac{2 π l}{{T}_{s}} ) . \qquad Eq . 6$$

Denoting a [n]=M_{λ}x[nTₛ], and using Poisson's formula, the following equation 7 may be derived:

$$A ( {e}^{j ω {T}_{s}} ) = {\sum }_{l ∈ ℤ} ℱ \{ {M}_{λ} x \} ( ω - \frac{2 π l}{{T}_{s}} ) . \qquad Eq . 7$$

Combining equations Eq. 6 and Eq. 7 yields equation 8 below:

$$A ( {e}^{j ω {T}_{s}} ) = Z ( ω ) . \qquad Eq . 8$$

Since y(t)=LPF (z(t)) with cutoff frequency of

$$\frac{π}{{T}_{s}} ,$$

we get equation 9 below:

$$Y ( ω ) = Z ( ω ) , \vert ω \vert \leq \frac{π}{{T}_{s}} \qquad Eq . 9$$

Sampling y(t) at rate Tₛ, which is its Nyquist rate, yields equation 10 below

$$DTFT \{ y [ n {T}_{s} ] \} ( {e}^{j ω {T}_{s}} ) = Y ( ω ) , \vert ω \vert \leq \frac{π}{{T}_{s}} . \qquad Eq . 10$$

It may be observed from these relationships that a [n] and y [nTₛ] have the same DTFT and are therefore identical. This approach therefore provides an alternative method for measuring M_{λ}x[nTₛ] using an ADC that does not need to handle higher frequencies. Once these samples are obtained, any existing modulo recovery method can be applied to deduce x[nTₛ] and, consequently, the input signal x(t).

According to some embodiments, recovery module 40 may be configured to apply a modulo recovery operation to digital output signal 160DS, to generate a digital recovered signal 40RS representative of the input signal 20A. As explained herein, digital output signal 160DS may be representative of the input signal 20A in its folded format (folded signal 140 MS). Recovery module 40 may process digital output signal 160DS to unfold or unwrap the modulo operation, thereby reconstructing a digital representation of the original input signal 20A.

According to some embodiments, modulo circuit 140 may include a folding indicator circuit configured to generate a 1-bit folding indication signal 140F, signifying whether modulo circuit 140 has applied a fold to input signal 20A since a previous sample. In some embodiments, fold indication 140F may indicate that a fold has occurred, without specifying the direction or the number of folds. In some embodiments, folding indicator circuit may incorporate folding indication 140F into a least significant bit (LSB) of digital output signal 160DS.

In some aspects, during digital processing, recovery module 40 may interpret the LSB as folding information rather than part of the measurement.

According to some embodiments, recovery module 40 may be configured to apply an unwrapping algorithm on digital output signal 160DS, based on folding indication 140F, to generate recovered signal 40RS representative of input signal 20A. Recovery module 40 may perform unwrapping when folding indication 140F indicates that a fold has occurred.

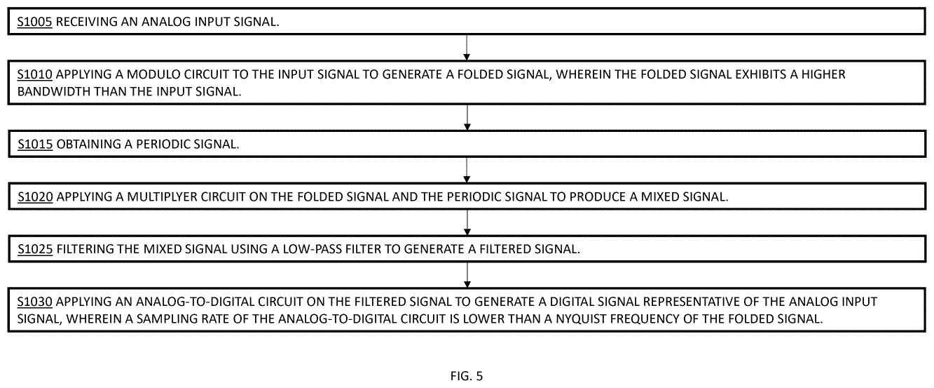

### FIG. 5

Reference is now made to FIG. 5, which is a flow diagram depicting an exemplary implementation of a method for processing an analog input signal, according to some embodiments of the invention.

At step S1005, the method may include receiving an analog input signal. Analog input signal 20A may be received, e.g., from input device 20, as shown in FIG. 4. In some aspects, input device 20 may include, for example, a sensor configured to detect physical phenomena and generate analog input signal 20A as an analog representation thereof.

At step S1010, the method may include applying a modulo circuit to the input signal to generate a folded signal that may exhibit a higher bandwidth than that of the input signal. As shown in FIG. 4, modulo circuit 140 may be configured to apply a modulo operation to analog input signal 20A to generate modulo signal 140 MS. Modulo signal 140 MS may exhibit a higher bandwidth than analog input signal 20A, as illustrated in FIG. 2C.

At step S1015, the method may include obtaining a periodic signal. According to some embodiments, periodic signal 150PS may be generated by signal generator 150, as shown in FIG. 4. In some aspects, signal generator 150 may include Step Recovery Diode (SRD) 153, which may be configured to generate periodic signal 150PS as a delta comb. Periodic signal 150PS may have a frequency Fₚ that exceeds a Nyquist frequency of analog input signal 20A and is lower than a Nyquist frequency of modulo signal 140 MS.

At step S1020, the method may include applying a multiplier circuit on the folded signal and the periodic signal to produce a mixed signal. As shown in FIG. 4, analog mixer 120 may be configured to multiply modulo signal 140 MS by periodic signal 150PS to produce mixed signal 120 MS. In some aspects, analog mixer 120 may be configured to convert modulo signal 140 MS and periodic signal 150PS to differential currents, and to multiply the differential currents using a trans-linear core as known in the art, to produce mixed signal 120 MS.

At step S1025, the method may include filtering the mixed signal using a low-pass filter to generate a filtered signal. As shown in FIG. 4, low-pass filter 130 may be configured to filter mixed signal 120 MS to generate a filtered signal 130FS. In some aspects, low-pass filter 130 may have a cutoff frequency that exceeds a Nyquist frequency of analog input signal 20A and is lower than a Nyquist frequency of modulo signal 140 MS.

At step S1030, the method may include applying an ADC circuit on the filtered signal to generate a digital signal representative of the folded signal, wherein a sampling rate of the ADC circuit is lower than a Nyquist frequency of the folded signal. As shown in FIG. 4, ADC 160 may be configured to sample filtered signal 130FS to generate digital signal 160DS. Digital signal 160DS may be representative of modulo signal 140 MS.

According to some embodiments, ADC 160 may be suited for digitizing analog signals having a bandwidth in the order of magnitude as that of the input analog signal, and may not be suited for digitizing arbitrary analog signals having a bandwidth in the order of modulo signal 140 MS.

For example, ADC 160 may have a sampling rate Fₛ that exceeds a Nyquist frequency of analog input signal 20A, but is lower than a Nyquist frequency of modulo signal 140 MS.

Additionally, or alternatively, ADC 160 may have an inherent transfer function having a bandwidth that exceeds the Nyquist frequency of analog input signal 20A, but is below the Nyquist frequency of modulo signal 140 MS.

Following step S1030, the method may further include applying a modulo recovery operation to the digital signal to generate a recovered signal representing a digital version of the input signal. As shown in FIG. 4, recovery module 40 may be configured to apply a modulo recovery operation to digital signal 160DS to generate recovered signal 40RS. Recovered signal 40RS may represent a digital version of analog input signal 20A.

The method may further include performing at least one software or hardware based operation on the recovered signal. As shown in FIG. 4, downstream application 50 may be configured to perform at least one software or hardware based operation on recovered signal 40RS. Such operations may include, for example, signal analysis, signal filtering, feature extraction, pattern recognition, data compression, data storage, data transmission, signal visualization, control system actuation, or any other digital signal processing operation, as required by the specific implementation.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

1. An electric circuit for sampling an input signal, the circuit comprising:
a modulo circuit configured to apply a modulo operation to the input signal, thereby generating a folded signal, wherein the folded signal exhibits a higher bandwidth than the input signal;
an analog mixer circuit configured to multiply the folded signal by a periodic signal to produce a mixed signal;
a low-pass filter circuit configured to filter the mixed signal, to generate a filtered signal; and
an Analog-to-Digital Converter (ADC) circuit having a bandwidth suited for the input signal, and configured to sample the filtered signal to generate a digital output signal representative of the folded signal.

2. The electric circuit of claim 1, associated with a recovery module, configured to apply a modulo recovery operation to the digital output signal, to generate a recovered signal representative of the input signal.

3. The electric circuit of claim 1 wherein a sampling rate Fₛ of the ADC circuit exceeds a Nyquist frequency of the input signal, and is lower than a Nyquist frequency of the folded signal.

4. The electric circuit of claim 1, wherein the periodic signal has a frequency Fₚ, wherein Fₚ exceeds a Nyquist frequency of the input signal, and is lower than a Nyquist frequency of the folded signal.

5. The electric circuit of claim 4 further comprising a signal generator module, comprising a Step Recovery Diode (SRD), wherein said SRD is configured to generate the periodic signal as a delta comb having frequency Fₚ.

6. The electric circuit of claim 1, wherein the low-pass filter circuit has a cutoff frequency that exceeds a Nyquist frequency of the input signal, and is lower than a Nyquist frequency of the folded signal.

7. The electric circuit of claim 1, further comprising a folding indicator circuit configured to:
generate a 1-bit folding indication, signifying whether the modulo circuit has applied a fold to the input signal since a previous sample; and
incorporate the folding indication into a least significant bit of the digital output signal.

8. The electric circuit of claim 7, associated with a modulo recovery circuit, wherein the modulo recovery circuit is configured to apply an unwrapping algorithm on the digital output signal, based on the folding indication, to generate a recovered signal representative of the input signal.

9. The electric circuit of claim 1, wherein the analog mixer circuit is configured to convert the folded signal and the periodic signal to differential currents, and to multiply the differential currents using a trans-linear core to produce the mixed signal.

10. A system for processing analog signals, the system comprising:
an input device, configured to generate an input signal;
a modulo circuit configured to apply a modulo operation to the input signal, thereby generating a folded signal, wherein the folded signal exhibits a higher bandwidth than the input signal;
an analog mixer circuit configured to multiply the folded signal by a periodic signal to produce a mixed signal;
a low-pass filter circuit configured to filter the mixed signal to generate a filtered signal;
an analog-to-digital converter circuit having a bandwidth suited for the input signal, and configured to sample the filtered signal at a sampling rate that is lower than a Nyquist frequency of the folded signal, to generate a digital output signal representative of the folded signal;
a modulo recovery circuit configured to apply a modulo recovery operation to the digital output signal to generate a digital recovered signal representative of the input signal; and
a processor configured to perform at least one software or hardware based operation based on the recovered signal.

11. The system of claim 10, wherein the periodic signal has a frequency Fₚ, wherein Fₚ exceeds a Nyquist frequency of the input signal, and is lower than a Nyquist frequency of the folded signal.

12. The system of claim 10, further comprising a signal generator module comprising a Step Recovery Diode (SRD), wherein said SRD is configured to generate the periodic signal as a delta comb.

13. The system of claim 10, further comprising a folding indicator circuit configured to:
generate a 1-bit folding indication signifying whether the modulo circuit has applied a fold to the input signal since a previous sample; and
incorporate the folding indication into a least significant bit of the digital output signal.

14. The system of claim 10, wherein the analog mixer circuit is configured to convert the folded signal and the periodic signal to differential currents, and to multiply the differential currents using a trans-linear core to produce the mixed signal.

15. A method of processing an analog input signal, the method comprising:
applying a modulo circuit to the input signal to generate a folded signal, wherein the folded signal exhibits a higher bandwidth than the input signal;
obtaining a periodic signal;
applying a multiplier circuit on the folded signal and the periodic signal to produce a mixed signal;
filtering the mixed signal using a low-pass filter to generate a filtered signal;
applying an analog-to-digital converter (ADC) circuit on the filtered signal to generate a digital signal representative of the folded signal, wherein a sampling rate of the ADC circuit is lower than a Nyquist frequency of the folded signal;
applying a modulo recovery operation to the digital signal to generate a recovered signal representing a digital version of the input signal; and
performing at least one software or hardware based operation on the recovered signal.

16. The method of claim 15, further comprising:
generating a 1-bit folding indication signifying whether a fold has been applied to the input signal since a previous sample;
incorporating the folding indication into a least significant bit of the digital signal; and
applying the modulo recovery operation by performing an unwrapping algorithm on the digital signal based on a folding indication.

17. The method of claim 15, wherein the analog input signal is generated by an input device selected from: a sensor, configured to detect physical phenomena and generate the analog input signal as an analog representation thereof, a transducer configured to convert physical quantities into electrical signals, a communication receiver configured to receive wired or wireless transmitted signals, and any combination thereof.

18. The method of claim 15, wherein performing the at least one software or hardware based operation on the recovered signal is selected from: performing signal analysis, performing signal filtering, performing feature extraction, performing pattern recognition, performing data compression, performing data storage, performing data transmission, performing signal visualization, performing control system actuation, and any combination thereof.
